(19) United States
(12) Patent Application Publication
(10) Pub. No.: US 2008/0217730 A1
(43) Pub. Date: Sep. 11, 2008

(54) METHODS OF FORMING GAS DIELECTRIC AND RELATED STRUCTURE

(76) Inventors: Toshiharu Furukawa, Essex Junction, VT (US); Mark C. Hakey, Fairfax, VT (US); Steven J. Holmes, Guilderland, NY (US); David V. Horak, Essex Junction, VT (US); Charles W. Koburger, Delmar, NY (US)

Correspondence Address: HOFFMAN WARNICK LLC, 75 STATE ST, 14TH FL, ALBANY, NY, 12207, US

(21) Appl. No.: 11/682,928

(22) Filed: Mar. 7, 2007

(51) Int. Cl. H01L 21/76

(52) U.S. Cl. 257/522; 438/422; 977/721; 257/E27.001; 257/E21.599; 977/755; 977/932

(57) ABSTRACT

Methods of forming a gas dielectric and a related structure are disclosed. In one embodiment, the method includes providing a wiring level including at least one conductive portion within a sacrificial dielectric; forming a nanofiber layer over the wiring level; vaporizing the sacrificial dielectric by heating; evacuating the vaporized sacrificial layer; and sealing pores in the nanofiber layer.

### BACKGROUND

1. Technical Field

The disclosure relates generally to integrated circuit (IC) chip fabrication, and more particularly, to methods of forming a gas dielectric and a related structure.

2. Background Art

In order to enhance IC chip operational speed, semiconductor devices have been continuously scaled down in size. Unfortunately, as semiconductor device size is decreased, the capacitive coupling between conductors in a circuit tends to increase since the capacitive coupling is inversely proportional to the distance between the conductors. This coupling may ultimately limit the speed of the chip or otherwise inhibit proper chip operation if steps are not taken to reduce the capacitive coupling.

The capacitance between conductors is also dependent on the insulator, or dielectric, used to separate the conductors. Traditional semiconductor fabrication commonly employs silicon dioxide (SiO₂) as a dielectric, which has a dielectric constant (k) of approximately 3.9. One challenge facing further development is finding materials with a lower dielectric constant that can be used between the conductors. As the dielectric constant of such materials is decreased, the speed of performance of the chip is increased. Some new low-k dielectric materials that have been used to provide a lower dielectric constant between conductors include, for example, fluorinated glass and organic materials. Unfortunately, provision of newer low-k dielectric materials presents a number of new challenges which increase process complexity and cost. For example, organic materials suffer from temperature limitations, shrinkage or swelling during manufacturing or chip operation, and poor structural integrity.

Instead of using SiO₂ and organic materials, another approach is to implement gas, such as air, which is provided in the form of a gas dielectric structure in a semiconductor structure. Simple capacitance modeling of parallel wires shows that even a small air-gap near the wire results in a significant improvement in the overall dielectric constant (k) for a structure, e.g., a 10% air gap per edge will reduce the effective dielectric constant of a dielectric by approximately 15%. Current processing for implementing a gas dielectric structure, however, is fairly complex and cannot be easily integrated into conventional damascene wire formation. Damascene wire formation is a process in which an interconnect pattern is first lithographically defined in the layer of dielectric, metal is then deposited to fill resulting trenches and then excess metal is removed by means of chemical-mechanical polishing (planarization). Typically, gas dielectric formation requires additional masking layers for reactive ion etching (RIE) processing steps relative to damascene wire formation. In addition, application of simple gas dielectric structures tends to create sagging of long line conductors as well as producing poor structural stability.

Currently, gas dielectric structures are typically formed by generating self-assembled nanostructures over a sacrificial dielectric and removing the dielectric by etching. One problem of this approach is that it requires several etch steps to form a nano-pattern in a hard mask to protect the wiring and then etch the dielectric under the hard mask to form the gas dielectric. In addition, it requires a thick nitride hard mask having enough mechanical integrity to remain in place after the underlying dielectric is removed.

### SUMMARY

Methods of forming a gas dielectric and a related structure are disclosed. In one embodiment, the method includes providing a wiring level including at least one conductive portion within a sacrificial dielectric; forming a nanofiber layer over the wiring level; vaporizing the sacrificial dielectric by heating; evacuating the vaporized sacrificial layer to form a gas dielectric; and sealing pores in the nanofiber layer.

A first aspect of the disclosure provides a method comprising: providing a wiring level including at least one conductive portion within a sacrificial dielectric; forming a nanofiber layer over the wiring level; vaporizing the sacrificial dielectric under the nanofiber layer by heating; evacuating the vaporized sacrificial dielectric; and sealing pores in the nanofiber layer.

A second aspect of the disclosure provides a structure comprising: a wiring level including at least one conductive portion; a nanofiber layer over the wiring level, the nanofiber layer including carbon nanotubes; and a gas dielectric in the wiring level below the nanofiber layer, the nanofiber layer including sealed pores on a surface thereof.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIGS. 1A, 1B and 2-4 show embodiments of a method of forming a gas dielectric, with FIG. 4 showing one embodiment of a structure.

FIG. 5 shows an alternative process.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

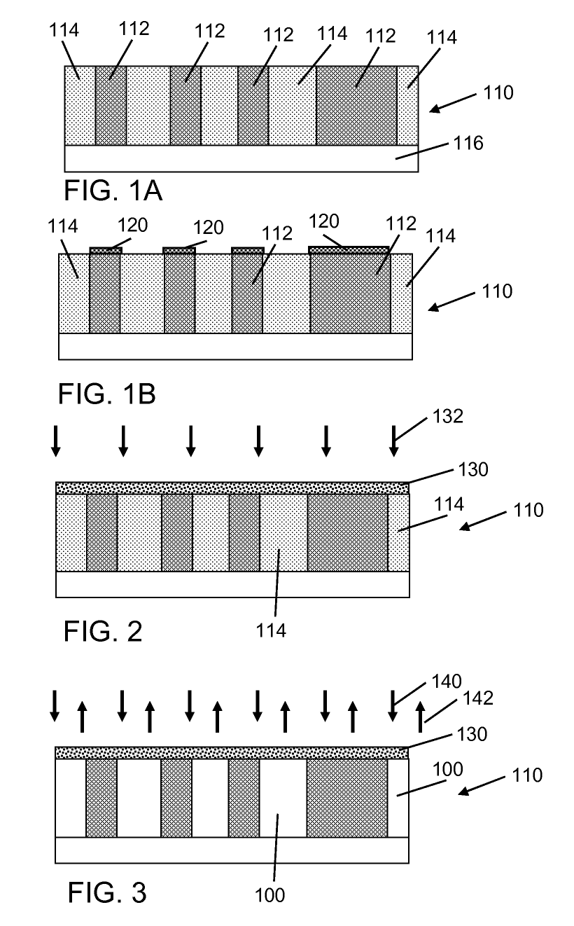

Referring to the drawings, FIGS. 1A, 1B and 2-4 show embodiments of a method of forming a gas dielectric 100 (FIG. 4), with FIG. 4 showing one embodiment of a related structure 102.

FIGS. 1A-B shows providing a wiring level 110 including at least one conductive portion 112 within a sacrificial dielectric 114. Sacrificial dielectric 114 is formed over a substrate or other lower wiring level 116. In one embodiment, sacrificial dielectric 114 includes an organic polymer such as alph-methyl-styrene, polymethacrylates, polycarbonates and other similar materials, for example, as described in U.S. Pat. No. 5,147,741 and U.S. Pat. No. 4,519,872. Where sacrificial dielectric 114 includes an organic polymer, it can be spin cast from organic solvent, to a thickness of approximately 300 nanometers (nm) to approximately 1000 nm, preferably approximately 500 nm to approximately 800 nm. The spin cast polymer is baked to remove solvent.

Wiring level 110 is otherwise provided using any now known or later developed techniques; only one example of which is described herein. Other processes, however, will be readily understood by those with ordinary skill in the art. In one example, a hard mask (not shown) such as silicon dioxide (SiO₂) or silicon nitride (Si₃N₄) can be vapor-deposited over sacrificial dielectric 114. The thickness of the hard mask is typically approximately 50 nm to approximately 200 nm. Photoresist (not shown) may be spin-applied over the hard mask, to a thickness of approximately 100 nm to approximately 300 nm, and lithographically patterned with the shapes for conductive portion(s) 112. The resist pattern is etched into the hard mask (for example, using reactive Ion etch (RIE) conditions: trifluoromethane-oxygen-argon (CHF₃/O₂/Ar) gases, 20-150 mtorr pressure and 500-1500 watts), and the hard mask pattern is transferred through sacrificial dielectric 114 with oxygen/argon (O₂/Ar) RIE. After etching the pattern, the spaces formed in the polymer are filled with metal (e.g., copper (Cu)) using conventional techniques, such as vapor deposition of a liner of tantalum (Ta), tantalum nitride (TaN) and/or ruthenium (Ru) to a thickness of approximately 1 nm to approximately 10 nm, and then metal 112 is plated over the liner to fill the spaces. After metal plating, the structure is planarized with chemical-mechanical polish (CMP), using the silicon dioxide or nitride film as a polish stop layer.

As an alternative, shown in FIG. 1B, a dielectric film 120 may be formed over each conductive portion 112 prior to the next process, i.e., forming a nanofiber layer 130 (FIG. 2). In particular, it may be desirable to place a dielectric material between a surface of conductive portion 112 (e.g., copper) and nanofiber layer 130 (FIG. 2). In one embodiment, dielectric film 120 can be a material such as a self-assembled layer, formed with poly-functional organic amines bound to a surface of each conductive portion 112. Note, dielectric film 120 is only shown in FIG. 1B for clarity.

FIG. 2 shows forming a nanofiber layer 130 over wiring level 110. In one embodiment, nanofiber layer 130 may be formed by spin casting a solvent solution. This process may include any now known or later developed process for spin casting nanofibers, e.g., the processes disclosed in U.S. Pat. Nos. 7,112,493 and 7,112,464, and similar to those processes used by, for example, Nantero Corp to make memory devices, or Brewer Science, Rolla, Mo. Nanofiber layer 130 is typically formed to a thickness of approximately 50 nm to approximately 300 nm, with approximately 100 nm to approximately 150 nm being preferable. In one embodiment, the nanofibers include carbon nanotubes, which may be single walled and/or multi-walled. The carbon nanotubes can be used in their native state. Alternatively, the carbon nanotubes can be chemically modified 132 on their surface. For example, the chemical modification may include depositing silicon dioxide to the carbon nanotubes or applying fluorine to the carbon nanotubes. Depositing silicon oxide insulates the carbon nanotubes electrically, and fluorination makes them non-conductive.

FIG. 3 shows vaporizing sacrificial dielectric 114 (FIG. 2) under nanofiber layer 130 by heating 140 to form gas dielectric 100. FIG. 3 also shows evacuating 142 the vaporized sacrificial dielectric 114, e.g., by applying a vacuum to a process chamber. In one embodiment, the pressure may range from approximately 10 millitorr (mtorr) to approximately 1 torr. However, the pressure could be higher such as between approximately 1 torr and approximately 50 torr, or even higher. Vaporized sacrificial dielectric 114 may exit through pores in nanofiber layer 130. The vaporizing may include heating to a temperature of, for example, no lower than approximately 250° C. and no greater than approximately 350° C. The heating occurs for a sufficient period of time to vaporize sacrificial dielectric 114 (e.g., organic polymer) remaining between conductive portions 112 (FIG. 2). Where organic polymer is used for sacrificial dielectric 114, the organic vapor passes up through pores in nanofiber layer 130, and is removed by means of vacuum 142 applied to the chamber containing the structure.

FIG. 4 shows sealing pores in nanofiber layer 130 (shown sealed), i.e., passivating nanofiber layer 130. In one embodiment, sealing includes oxidizing a surface 150 of nanofiber layer 130. Oxidizing may include, for example: exposing surface 150 to an oxygen or ozone plasma treatment; activating surface 150 with trimethyl aluminum (Al(CH₃)₃)(TMAl) (e.g., at 25° C.) and exposing surface 150 to tris(t-butoxy) silanol vapor to grow a thin layer of silicon oxide 152. As shown in FIG. 4, this process also forms a thin layer of silicon oxide 154 about gas dielectric 100. Film growth of approximately 2 nm to approximately 20 nm can be achieved, with a preferred thickness of approximately 5 nm to approximately 10 nm of oxide growth. Alternatively, the oxidizing may include applying tetraethyl orthosilicate, Si(OC₂H₅)₄ (TEOS) to surface 150 to form a thin layer of silicon oxide 152.

FIG. 4 also shows embodiments of structure 102. In one embodiment, structure 102 includes wiring level 110 including at least one conductive portion 112, a nanofiber layer 130 over wiring level 110, the nanofiber layer including carbon nanotubes. Gas dielectric 100 is positioned in wiring level 110 below nanofiber layer 130, the nanofiber layer including sealed pores on surface 150 thereof. As noted above, carbon nanotubes may be single walled and/or multi-walled.

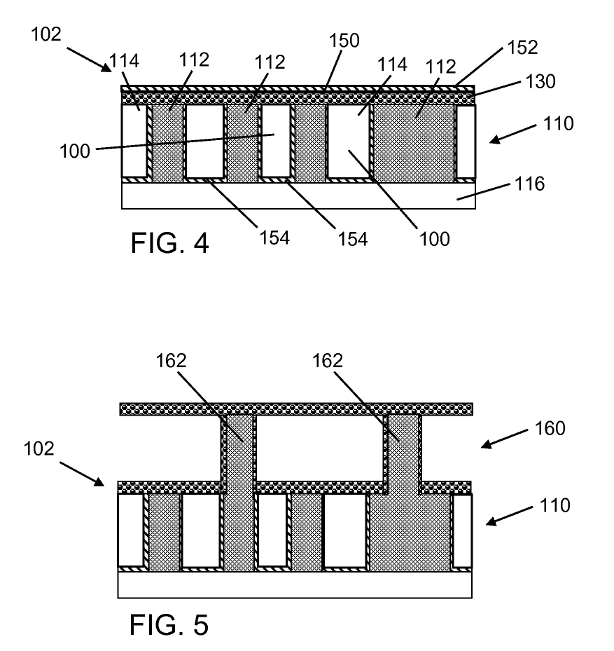

At this point, as shown in FIG. 5, the process can begin again for a via level or next wiring level 160, using the same sequence of process steps. Alternatively, a conventional dielectric deposition and via formation process could be performed, allowing more structural integrity for the overall back-end-of-line (BEOL) structure by avoiding the use of gas dielectrics for the vias, but using it for wiring levels. As shown, in one embodiment, each via 162 coupling to conductive portions 112 is fully landed so as not to cause shorting or opening of gas dielectric 100.

The methods as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A method comprising:
providing a wiring level including at least one conductive portion within a sacrificial dielectric;
forming a nanofiber layer over the wiring level;
vaporizing the sacrificial dielectric under the nanofiber layer by heating;
evacuating the vaporized sacrificial dielectric to form a gas dielectric; and
sealing pores in the nanofiber layer.

2. The method of claim 1, wherein the nanofiber layer includes carbon nanotubes.

3. The method of claim 2, wherein the carbon nanotubes are at least one of single walled and multi-walled.

4. The method of claim 2, further comprising chemically modifying the carbon nanotubes.

5. The method of claim 4, wherein the chemical modifying includes one of: depositing silicon dioxide to the carbon nanotubes and applying fluorine to the carbon nanotubes.

6. The method of claim 1, wherein the sacrificial dielectric includes an organic polymer.

7. The method of claim 1, wherein the nanofiber layer forming includes spin casting a solvent solution.

8. The method of claim 1, further comprising forming a dielectric film over each conductive portion prior to forming the nanofiber layer.

9. The method of claim 8, wherein the dielectric film forming includes forming a self-assembled layer using poly-functional organic amines bound to a surface of each conductive portion.

10. The method of claim 8, wherein the dielectric film forming includes forming an oxide or fluorine functionalized surface layer on each conductive portion.

11. The method of claim 1, wherein the vaporizing includes heating to a temperature no lower than approximately 250° C. and no greater than approximately 350° C.

12. The method of claim 1, wherein the sealing includes oxidizing a surface of the nanofiber layer.

13. The method of claim 12, wherein the oxidizing includes one of:
a) exposing the surface to an oxygen or ozone plasma;
b) activating the surface with trimethyl aluminum and exposing the surface to tris(t-butoxy) silanol vapor; and
c) applying tetraethyl orthosilicate, Si(OC₂H₅)₄ (TEOS) to the surface.

14. A structure comprising:
a wiring level including at least one conductive portion;
a nanofiber layer over the wiring level, the nanofiber layer including carbon nanotubes; and
a gas dielectric in the wiring level below the nanofiber layer, the nanofiber layer including sealed pores on a surface thereof.

15. The structure of claim 14, wherein the carbon nanotubes are one of: single walled and multi-walled.
